(19) United States
(12) Patent Application Publication
(10) Pub. No.: US 2011/0048493 A1
(43) Pub. Date: Mar. 3, 2011

(54) SOLAR CELL

(75) Inventors: Sun Jin YUN, Daejeon (KR); JungWook Lim, Daejeon (KR); Je Ha Kim, Daejeon (KR)

(73) Assignee: ELECTRONICS AND TELECOMMUNICATIONS RESEARCH INSTITUTE, Daejeon (KR)

(21) Appl. No.: 12/874,114

(22) Filed: Sep. 1, 2010

(30) Foreign Application Priority Data
Sep. 2, 2009 (KR) 10-2009-0082486
Dec. 30, 2009 (KR) 10-2009-0134517

(51) Int. Cl. H01L 31/0216; H01L 31/042

(52) U.S. Cl. 136/244; 136/256

(57) ABSTRACT

Provided is a solar cell. The solar cell includes a photovoltaic conversion device having first surface and the second surface on the opposite side, a first electrode connected to the first surface, a second electrode connected to the second surface, and an alkaline metal containing layer contacting one of the first and second electrodes.

### CROSS-REFERENCE TO RELATED APPLICATIONS

This U.S. non-provisional patent application claims priority under 35 U.S.C. §119 of Korean Patent Application Nos. 10-2009-0082486, filed on Sep. 2, 2009, and 10-2009-0134517, filed on Dec. 30, 2009, the entire contents of which are hereby incorporated by reference.

### BACKGROUND OF THE INVENTION

The present invention disclosed herein relates to a solar cell.

A solar cell is a photovoltaic energy conversion system that converts light energy from the sun into electric energy. When the light is incident on the solar cell, electron-hole pairs are generated in a semiconductor. By electric field generated in a P-N junction, the electrons move to an N-type semiconductor and the holes move to a P-type semiconductor, thereby generating electric power.

The solar cell generates the electric power using the sun as a light source. Therefore, the solar cell does not generate pollution during the generation of the electric power and thus the solar cell is getting the spotlight as a future-oriented, environment-friendly energy source. However, since the solar cell has relatively lower photovoltaic energy conversion efficiency, it is difficult to put the solar cell to practical use. Accordingly, in order to put the solar cells to the practical use, many researches for improving the photovoltaic energy conversion efficiency have been making much progress.

### SUMMARY OF THE INVENTION

The present invention provides a solar cell having high reliability.

The present invention also provides a solar cell having high efficiency.

Embodiments of the present invention provide solar cells including a solar cell including: a photovoltaic conversion device including a first surface and a second surface on the opposite side; a first electrode connected to a first surface of the photovoltaic conversiondevice; a second electrode connected to a second surface of the photovoltaic conversiondevice; and an alkaline metal containing layer contacting one of the first and second electrodes. In some embodiments, the alkaline metal containing layer is composed of nanoparticles in which one particle is isolated from each other. In some other embodiments, the alkaline metal containing layer may be provided in the form of a thin film

In some embodiments, the alkaline metal containing layer may be provided in the form of a thin film on the second electrode to function as a antireflection layer. At this point, the second electrode is disposed between the alkaline metal containing layer and the photovoltaic conversion layer.

In other embodiments, the solar cell may further include a glass substrate disposed on the alkaline metal containing layer; and a antireflection layer disposed on the glass substrate. At this point the alkaline metal containing layer may be disposed between the glass substrate and the second electrode. The glass substrate may be disposed between the antireflection layer and the alkaline metal containing layer. The alkaline metal containing layer may have a greater refractive index than the glass substrate and a less refractive index than the second electrode.

In still other embodiments, the first electrode may include a first surface contacting the photovoltaic conversion device and a second surface on the opposite side. At this point, the solar cell may further include a substrate covering the second surface of the first electrode and a metal grid contacting the second electrode through the alkaline metal containing layer.

In even other embodiments, the solar cell may further include an antireflection layer on the alkaline metal containing layer. At this point, the metal grid further passes through the antireflection layer.

In yet other embodiments, the first electrode may include a first surface contacting the photovoltaic conversion device and a second surface on the opposite side, and the alkaline metal containing layer covers the second surface of the first electrode.

In further embodiments, the solar cell may further include a glass substrate on the second electrode; and an antireflection layer on the glass substrate. At this point, the glass substrate may be disposed between the second electrode and the antireflection layer.

In still further embodiments, the solar cell may further include a metal grid contacting the first electrode through the alkaline metal containing layer.

In even further embodiments, the alkaline metal containing layer may have a higher reflectance for a first wavelength band of incident light than a second wavelength band of the incident light. At this point, the first wavelength band may be different from the second wavelength band.

In yet further embodiments, the second wavelength band may include visible light.

In still yet other embodiments, the solar cell may further include an additional alkaline metal containing layer on the second electrode. At this point, the second electrode may be disposed between the additional alkaline metal containing layer and the photovoltaic conversion layer.

In still further other embodiments, the alkaline metal containing layer may cover a top surface of the photovoltaic conversion device to function as an antireflection layer and the second electrode may be a metal grid connected to the photovoltaic conversion layer through the alkaline metal containing layer.

In still yet other embodiments, the first electrode may include a first surface contacting the photovoltaic conversion device and a second surface on the opposite side. At this point, the solar cell further includes an additional alkaline metal containing layer covering the second surface of the first electrode.

In still further other embodiments, the alkaline metal containing layer may be disposed between the first surface of the photovoltaic conversion device and the first electrode and electrically may connect the photovoltaic conversion device to the first electrode.

In still yet other embodiments, one of the first and second electrodes, which contacts the alkaline metal containing layer, may include a halogen element or a group-VI element.

In still further yet other embodiments, the alkaline metal containing layer may include alkaline metal bonded to oxygen, boron, hydrogen, or fluorine.

In still yet other embodiments, an amount of alkaline metal contained in the alkaline metal containing layer may be about 5-20 percent by weight.

In still further yet other embodiments, the photovoltaic conversion layer may include a plurality of PIN diodes.

In still further yet other embodiments, the photovoltaic conversion layer may include a plurality of PN diodes.

In still yet other embodiments, the photovoltaic conversion device may include at least one of Si, SiGe, CuInS, CuInSe, CuInGaSe, CuInGaS, CdS, CdTe, ZnO, ZnS, CuZnSnS, CuZnSnSe, Cu₂O, GaAs, GaInAs, GaInAlAs, and InP.

In still further yet other embodiments, some of alkaline metal contained in the alkaline metal containing layer may be diffused to the photovoltaic conversion layer through one of the first and second electrodes, which contacts the alkaline metal containing layer.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIGS. 1A to 1D are views illustrating a solar cell according to first embodiment;

FIGS. 2A to 2C are views illustrating a solar cell according to second embodiment;

FIGS. 3A to 3C are views illustrating a solar cell according to third embodiment;

FIGS. 4A and 4B are views illustrating a solar cell according to fourth embodiment;

FIGS. 5A and 5B are views illustrating a photovoltaic conversion layer included in solar cell according to embodiments of the present invention.

FIGS. 6A and 6B are views illustrating a metal grid included in the solar cell according to embodiments of the present invention; and

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. In the drawings, the dimensions of layers and regions are exaggerated for clarity of illustration. It will also be understood that when a layer (or film) is referred to as being ‘on’ another layer or substrate, it can be directly on the other layer or substrate, or intervening layers may also be present. Further, it will be understood that when a layer is referred to as being ‘under’ another layer, it can be directly under, and one or more intervening layers may also be present. In addition, it will also be understood that when a layer is referred to as being ‘between’ two layers, it can be the only layer between the two layers, or one or more intervening layers may also be present. Like reference numerals refer to like elements throughout.

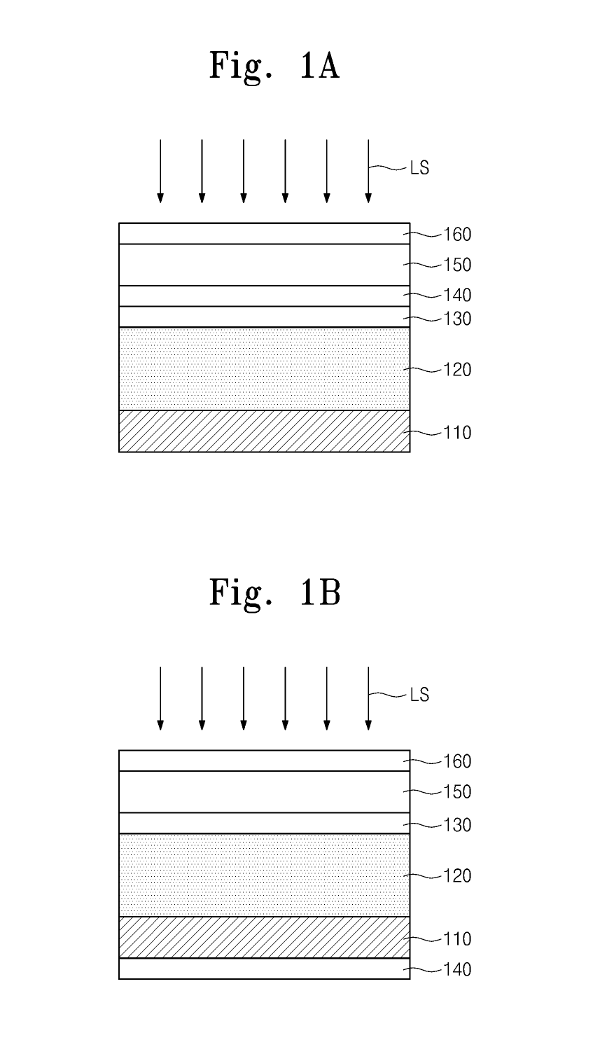

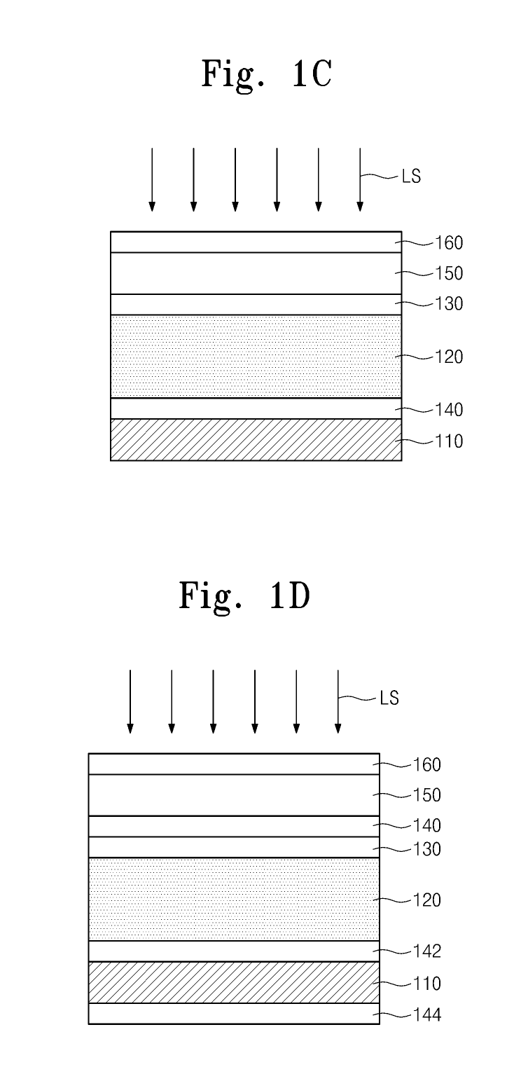

A solar cell will now be described according to first embodiment of the present invention. FIG. 1A is a view of a solar cell according to first embodiment.

Referring to FIG. 1A, a photovoltaic conversion device 120 is provided. The photovoltaic conversion layer 120 is configured to generate carriers (e.g., holes and electrons) by the sunlight incident thereon. The photovoltaic conversion device 120 includes a first surface and a second surface on the opposite side. The photovoltaic conversion device 120 may include a first conductive semiconductor layer, a second conductive semiconductor layer, and an intrinsic semiconductor layer. The first conductive semiconductor layer may be a p-type semiconductor and the second conductive semiconductor layer may be a n-type semiconductor layer. The intrinsic semiconductor layer may be disposed between the first and second conductive semiconductor layers. The first conductive semiconductor layer may be spaced apart from the second conductive semiconductor layer. The photovoltaic conversion device may include a first conductive semiconductor layer and a second conductive semiconductor layer. The first conductive semiconductor layer may be a p-type semiconductor and the second conductive semiconductor layer may be a n-type semiconductor layer.

The first and second surfaces of the photovoltaic conversion device 120 may be surfaces included to different types of semiconductor layers. For example, the first surface of the photovoltaic conversion device 120 may be a surface included in an N-type semiconductor layer and the second surface of the photovoltaic conversion device 120 may be a surface included in a P-type semiconductor layer. The photovoltaic conversion device 120 may include at least one of Si, SiGe, CuInS, CuInGaSe, CuInGaS, CdS, CdTe, ZnO, ZnS, CuZnSnS, CuZnSnSe, Cu₂O, GaAs, GaInAs, GaInAlAs, and InP. The photovoltaic conversion device 120 may has a multi junction structure or a heterojunction with intrinsic thin layer (HIT).

The first surface of the photovoltaic conversion device 120 may be connected to a first electrode 110. The first electrode 110 may cover the first surface of the photovoltaic conversion device 120. The first electrode 110 may directly contact the first surface of the photovoltaic conversion device 120. The second surface of the photovoltaic conversion device 120 may be connected to a second electrode 130. The second electrode 130 may cover the second surface of the photovoltaic conversion device 120. The second electrode 130 may directly contact the second surface of the photovoltaic conversion device 120.

The first electrode 110 may include metal. For example, the first electrode 110 may include silver (Ag), platinum (Pt), nickel (Ni), chrome (Cr), aluminum (Al), titanium (Ti), molybdenum (Mo), or tungsten (W). Alternatively, the first electrode 110 may include a transparent conductive material. For example, the first electrode 110 may include one of ZnO:Al, ZnO:Ga, ZnO:B, ZnO:Cd, InO, InSnO, SnO₂, SnO:F, RuO₂, IrO₂, and Cu₂O.

The second electrode 130 may include a transparent conductive material. For example, the second electrode 130 may include one of ZnO:Al, ZnO:Ga, ZnO:B, ZnO:Cd, InSnO (ITO), SnO₂, SnO:F, RuO₂, IrO₂, and Cu₂O. The second electrode 130 may include electric charge compensation material. The electric charge compensation material may be a halogen element or a group-VI element. For example, the second electrode 130 may include one of fluorine (F), chlorine (Cl), bromine (Br), iodine (I), oxygen (O), sulphur (S), selenium (Se), and tellurium (Te). The electric charge compensation material enhances conductivity of the second electrode 130.

The alkaline metal containing layer 140 may be formed on the glass substrate 150 coated with antireflection layer 160 on the opposite side. The second electrode 130 may be disposed between the alkaline metal containing layer 140 and the photovoltaic conversion device 120.

The alkaline metal containing layer 140 may include alkaline metal. For example, the alkaline metal may be sodium (Na). An amount of the alkaline metal compound in the alkaline metal containing layer 140 may be about 5-20% by weight. The alkaline metal containing layer 140 may contain the alkaline metal in a state where it is bonded with oxygen (O), boron (B), hydrogen (H), or fluorine (F). When the alkaline metal is the sodium (Na), the alkaline metal containing layer 140 may exist in the form of at least one of NaF, NaO, NaAlO₂, Na₂O-Al₂O₃-nSiO₂ (n is integer), NaBO₂, Na₂B₄O₇, NaBH₄, Na₂C₂, NaBH₄, Na₂O₂, Na₂Si₂O₅, Na₂SiO₃, and Na₄SiO₄ in a thin film including at least one of Al₂O₃, TiO₂, AlTiO, SiO₂, Si₃N₄, SiON, ZnO, ZnS, ZnSe, ZrO₂, HfO₂, MO, CuO, and Ta₃O₅ thin films. Alternatively, the alkaline metal containing layer 140 may be formed of a material containing a precursor including at least one of NaF, NaO, NaAlO₂, Na₂O-Al₂O₃-nSiO₂ (n is integer), NaBO₂, Na₂B₄O₇, NaBH₄, Na₂C₂, NaBH₄, Na₂O₂, Na₂Si₂O₅, Na₂SiO₃, and Na₄SiO₄. Conductivity of the alkaline metal containing layer 140 may be properly adjusted depending on whether there is a need for electrical connection. The alkaline metal containing layer 140 may be formed using a solution precursor through a sol-gel process, a spin-coating process, an imprinting process, a spray process, a dipping process, or screen-printing process. Alternatively, the alkaline metal containing layer 140 may be formed through a sputtering deposition process, an evaporation process, or a chemical vapor deposition process.

The alkaline metal containing layer 140 may have a larger refractive index than the glass substrate 150 and have a smaller refractive index than the second electrode 130. The refractive index of the alkaline metal containing layer 140 may be a square root of a value attained by multiplying the refractive index of the glass substrate 150 by the refractive index of the second electrode 130. The alkaline metal containing layer 140 may perform as a antireflection layer that reduces the reflection of the incident light.

The alkaline metal of the alkaline metal containing layer 140 may be diffused to the photovoltaic conversion device 120 through the second electrode 130. The alkaline metal diffused to the photovoltaic conversion device 120 removes the defectiveness in the photovoltaic conversion device 120 to improve the photovoltaic conversion efficiency of the photovoltaic conversion device 120, thereby providing a high efficiency solar cell. The alkaline metal diffused to the photovoltaic conversion device 120 passivates defects in the photovoltaic conversion device 120 to improve the photovoltaic conversion efficiency of the photovoltaic conversion device 120, thereby providing a high efficiency solar cell.

The glass substrate 150 may be a sodalime glass substrate. Alternatively, the glass substrate 150 may be a glass substrate that does not contain sodium (Na).

The antireflection layer 160 may include an incident surface on which the light is incident from a light source LS. The light source LS may be the sun. The light introduced through the antireflection layer 160 may be directed to the photovoltaic conversion device 120 through the glass substrate 150, the alkaline metal containing layer 140, and the second electrode 130. The antireflection layer 160 is configured to minimize the reflection of the light incident from the light source LS on a surface of the glass substrate 150. The antireflection layer 160 may include at least one of aluminum-titanium oxide, silicon-titanium oxide, aluminum-zirconium oxide, zirconium-titanium oxide, hafnium-titanium oxide, zirconium oxide, titanium oxide, magnesium fluoride, magnesium oxide, hafnium oxide, aluminum oxide, silicon oxide, and nitride-silicon oxide.

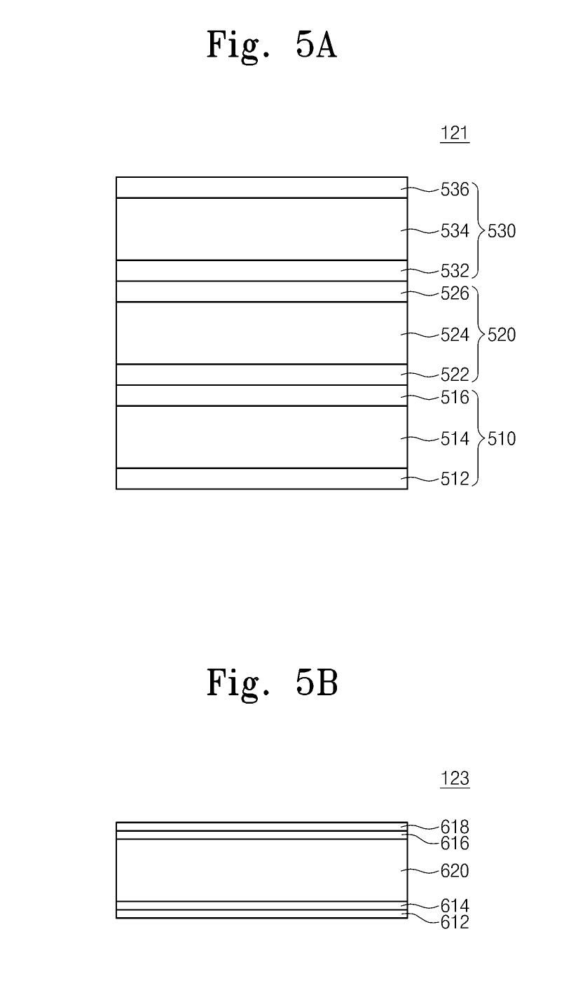

The following will describe modified examples of the photovoltaic conversion device 120 of solar cell according to embodiments of present invention. FIGS. 5A and 5B are views illustrating modified examples of the photovoltaic conversion layer of solar cell according to embodiments of present invention.

Referring to FIG. 5A, a photovoltaic conversion device 121 may be a multiple junction structure including first, second, and third PIN diodes 510, 520, and 530. The first PIN diode 510 may include a first semiconductor layer 512 of a first conductive type, a second semiconductor layer 514 of an intrinsic state on the first semiconductor layer 512, and a third semiconductor layer 516 of a second conductive type. The second PIN diode 520 may be disposed on the third semiconductor layer 516 of the first PIN diode 510. The second PIN may include a fourth semiconductor layer 522 of the first conductive type, a fifth semiconductor layer 524 of the intrinsic state, and a sixth semiconductor layer 526 of a second conductive type, which are sequentially stacked on the third semiconductor layer 516. The third PIN diode 530 may be disposed on the sixth semiconductor layer 526 of the second PIN diode 520. The third PIN diode 530 may include a seventh semiconductor layer 532 of the first conductive type, an eighth semiconductor layer 534 of the intrinsic state, and a ninth semiconductor layer 536 of the second conductive type, which are consecutively stacked on the sixth semiconductor layer 526. The 510, 520, and 530 diodes may be composed only two types of semiconductor layers such as the first conductive type semiconductor layer and the second conductive semiconductor layer. That is, the 510, 520, and 530 diodes may be PN diodes. Although three PIN diodes 510, 520, and 530 are illustrated in FIG. 5A, the present invention is not limited to this. For example, the photovoltaic conversion layer 121 may include two or more than four PIN diodes.

Referring to FIG. 5B, a photovoltaic conversion layer 123 may has a heterojunction with intrinsic thin layer (HIT) structure including a single-crystal layer and amorphous silicon layers. The photovoltaic conversion layer 123 includes a first amorphous silicon layer 612 of a first conductive type, a second amorphous silicon layer 614 of an intrinsic state, a single-crystal silicon layer 620 of the first conductive type, a third amorphous silicon layer 616 of the intrinsic state, and a fourth amorphous silicon layer 618 of a second conductive type. The first conductive type may be an N-type. The amorphous silicon layers 612, 614, 616, and 618 may be thinner than the single-crystal silicon layer 620.

The following will describe modified examples of the solar cell according to first embodiment of the present invention.

FIG. 1B is a view of first modified example of the solar cell according to first embodiment of the present invention.

Referring to FIG. 1B, the first and second electrodes 110 and 130 described with reference to FIG. 1A may be provided. One of the photovoltaic conversion devices 120, 121, and 123 described with reference to FIGS. 1A, 5A, and 5B may be provided. The second electrode 130 may be disposed on a glass substrate 150. The second electrode 130 may be disposed between the glass substrate 150 and the photovoltaic conversion device 120. An antireflection layer 160 may be disposed on the glass substrate 150. The glass substrate 150 may be disposed between the second electrode 130 and the antireflection layer 160. The glass substrate 150 and the antireflection layer 160 may be formed of same materials as the glass substrate 150 and the antireflection layer 160 of FIG. 1A.

The first electrode 110 may include a first surface contacting the photovoltaic conversion device 120 and a second surface opposite to the first surface. An alkaline metal containing layer 140 may be disposed on the second surface of the first electrode 110. The alkaline metal containing layer 140 may cover the second surface of the first electrode 110. The first electrode 110 may be disposed between the alkaline metal container layer 140 and the photovoltaic conversion device 120. The alkaline metal containing layer 140 may be formed of a same material as the alkaline metal containing layer 140 of FIG. 1A. The alkaline metal contained in the alkaline metal containing layer 140 may be diffused to the photovoltaic conversion device 120 through the first electrode 110.

FIG. 1C is a view of second modified example of the solar cell according to first embodiment of the present invention.

Referring to FIG. 1C, the second electrode 130, glass substrate 150, and antireflection layer 160, which are described with reference to FIG. 1A may be provided. One of the photovoltaic conversion devices 120, 121, and 123 described with reference to FIGS. 1A, 5A, and 5B may be provided. The photovoltaic conversion device 120 may include a first surface and a second surface on the opposite side. The second surface of the photovoltaic conversion device 120 may contact the second electrode 130. The first electrode 110 may be disposed on the first surface of the photovoltaic conversion device 120. The alkaline metal containing layer 140 may be disposed between the first electrode 110 and the photovoltaic conversion device 120. The alkaline metal containing layer 140 may include a conductive material. The alkaline metal containing layer 140 may electrically interconnect the first surface of the photovoltaic conversion device 120 and the first electrode 110. The alkaline metal containing layer 140 functions as a reflective layer reflecting the light passing through the photovoltaic conversion device 120. The light reflected by the alkaline metal containing layer 140 may be re-entered into the photovoltaic conversion device 120. The alkaline metal containing layer 140 may be formed of a same material as the alkaline metal containing layer 140 described with reference to FIG. 1a.

FIG. 1D is a view of third modified example of the solar cell according to first embodiment of the present invention.

Referring to FIG. 1D, the second electrode 130, alkaline metal containing layer 140, glass substrate 150, and antireflection layer 160, which are described with reference to FIG. 1A may be provided. One of the photovoltaic conversion devices 120, 121, and 123 described with reference to FIGS. 1A, 5A, and 5B may be provided.

The photovoltaic conversion device 120 may include a first surface and a second surface on the opposite side. The second surface of the photovoltaic conversion device 120 may contact the second electrode 130. The first electrode 110 may be disposed on the first surface of the photovoltaic conversion device 120. A first additional alkaline metal containing layer 142 may be disposed between the first electrode 110 and the photovoltaic conversion device 120. The first additional alkaline metal containing layer 142 may be the alkaline metal containing layer 140 that is described with reference to FIG. 1C.

The first electrode 110 may include a first surface contacting the first additional alkaline metal containing layer 142 and a second surface on the opposite side. A second additional alkaline metal containing layer 144 may be disposed on the second surface of the first electrode 110. The first electrode 110 may be disposed between the first and second additional alkaline metal containing layer 142 and 144. The second additional alkaline metal containing layer 144 may be formed of a same material as the alkaline metal containing layer 140.

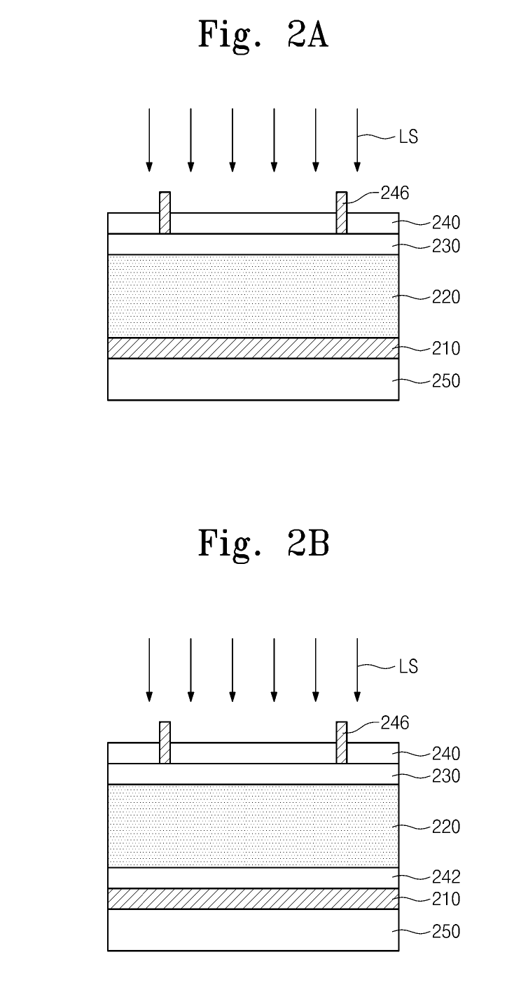

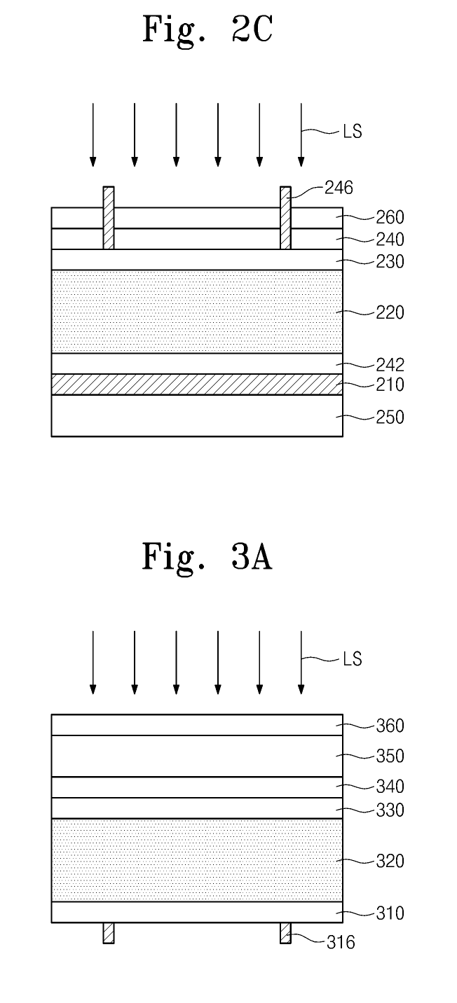

A solar cell according to second embodiment will be described hereinafter. FIG. 2A is a view of a solar cell according to second embodiment.

Referring to FIG. 2A, a first electrode 210, a photovoltaic conversion device 220, and a second electrode 230 are consecutively stacked on a substrate 250. The photovoltaic conversion device 220 may be one of the photovoltaic conversion devices 120,121, and 123 that are described with reference to FIGS. 1A, 5A, and 5B. The first and second electrodes 210 and 230 may be same as the first and second electrodes 110 and 130 described with reference to FIG. 1A.

The first electrode 210 may include a first surface contacting the photovoltaic conversion device 220 and a second surface on the opposite side. The substrate 250 may contact the second surface of the first electrode 210. The substrate 250 may be the glass substrate 150 that is described with reference to FIG. 1A. Alternatively, the substrate 250 may be an opaque substrate. For example, the substrate 250 may be one of a stainless steel substrate, a copper substrate, a plastic substrate, a ceramic substrate, a flexible polymer substrate, or a flexible metal substrate.

An alkaline metal containing layer 240 may be disposed on the second electrode 230. The alkaline metal containing layer 240 may be formed of a same material as the alkaline metal containing layer 140 of FIG. 1A. The alkaline metal containing layer 240 may include an incident surface on which the light is incident from a light source LS. The alkaline metal containing layer 240 may have a smaller refractive index than the second electrode 230. The alkaline metal containing layer 240 is configured to minimize reflection of the light incident from the light source LS.

A metal grid may 246 may be disposed to pass through the alkaline metal containing layer 240 and contact the second electrode 230. The metal grid 246 may protrude from the alkaline metal containing layer 240. The metal grid 246 may include at least one of silver (Ag), gold (Au), platinum (Pt), nickel (Ni), Copper (Cu), Carbon (C), Chrome (Cr), Aluminum (Al), titanium (Ti), and molybdenum (Mo), and tungsten (W). The metal grid 246 may have a higher conductivity than the second electrode 230. By the metal grid 246 of smaller resistivity, carriers generated in the photovoltaic conversion device 220 by the light source LS may be collected from the second electrode 230 and delivered to DC or AC load device with smaller loss of carriers. The metal grid 246 may be formed after forming the alkaline metal containing layer 240 on the second electrode 230. In this case, after the metal grid 246 is formed, the metal in the metal grid 246 diffuses through the alkaline metal containing layer 240 by a heat-treatment process and the metal grid 246 is electrically connected to the second electrode 230.

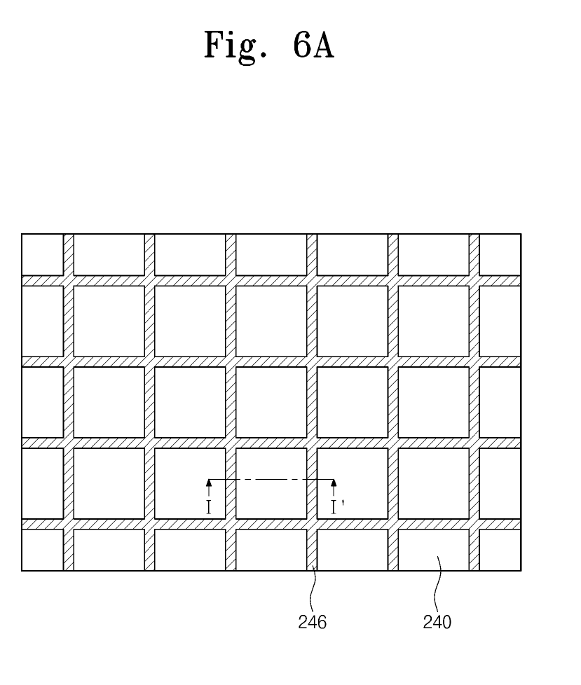

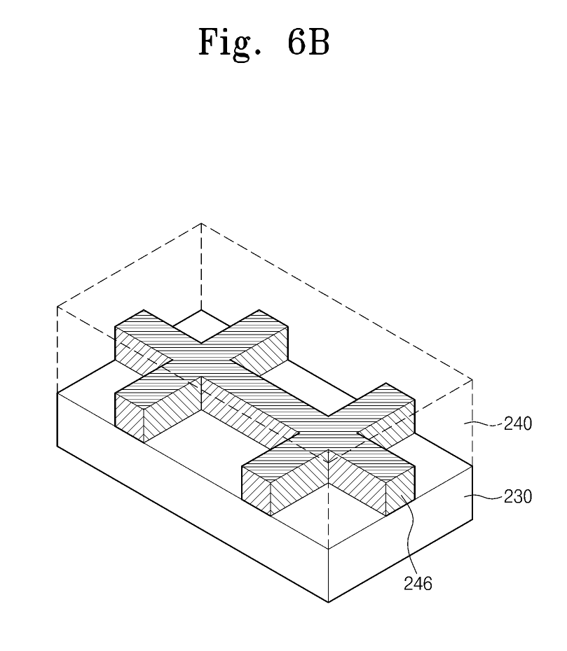

The following will describe the metal grid. FIG. 6A is a top plane view for illustrating the metal grid of FIG. 2A. FIG. 2A is a cross-sectional view taken along line I-I′ of FIG. 6A.

Referring to FIG. 2A and 6A, the metal grid 246 may extend in a first direction in parallel with the second surface of the photovoltaic conversion layer 220. The metal grid 246 may extend in a second direction that is in parallel with the second surface of the photovoltaic conversion layer 220 and intersects the first direction. The second direction may intersect the first direction at a right angle. Alternatively, the metal grid 246 may be composed of a plurality of conductive lines extending in the first direction.

FIG. 6B is a perspective view of a modified example of the metal grid of FIG. 6A.

Referring to FIG. 6B, the metal grid 246 is disposed between the alkaline metal containing layer 240 and the second electrode 230. The metal grid 246 may extend in a first direction in parallel with the second surface of the photovoltaic conversion device 220. The metal grid 246 may extend in a second direction that is in parallel with the second surface of the photovoltaic conversion device 220 and intersects the first direction. The second direction may intersect the first direction at a right angle. In this case, the alkaline metal containing layer 240 may be formed after the metal grid 246 is formed on the second electrode 230. Alternatively, the metal grid 246 may be composed of a plurality of conductive lines extending in the first direction.

The following will describe modified examples of the solar cell according to second embodiment of the present invention.

FIG. 2B is a view of first modified example of the solar cell according to second embodiment of the present invention.

Referring to FIG. 2B, the photovoltaic conversion device 220, second electrode 230, alkaline metal containing layer 240, and metal grid 246, which are described with reference to FIG. 2A, may be provided. The photovoltaic conversion device 220 may include a first surface and a second surface on the opposite side.

The second surface of the photovoltaic conversion device 220 may contact the second electrode 230. The first electrode 210 may be disposed on the second surface of the photovoltaic conversion device 220. The first electrode 210 may be formed of a same material as the first electrode 210 of FIG. 2A.

An additional alkaline metal containing layer 242 may be disposed between the first electrode 210 and the first photovoltaic conversion device 220. The first electrode 210 may include a first surface contacting the additional alkaline metal containing layer 242 and a second surface on the opposite side. The substrate 250 may be disposed on the second surface of the first electrode 210. The substrate 250 may be the substrate of FIG. 2A.

The additional alkaline metal containing layer 242 may include a conductive material. The additional alkaline metal containing layer 242 may electrically connect the first surface of the photovoltaic conversion device 220 to the first electrode 210. The additional alkaline metal containing layer 242 may function as a reflective layer reflecting the light passing through the photovoltaic conversion device 220. The light reflected on the additional alkaline metal containing layer 242 may be re-entered into the photovoltaic conversion device 220. The additional alkaline metal containing layer 242 may be formed of a same material as the alkaline metal containing layer described with reference to FIG. 1A.

FIG. 2C is a view of second modified example of the solar cell according to second embodiment of the present invention.

Referring to FIG. 2C, the substrate 250, first electrode 210, additional alkaline metal containing layer 242, photovoltaic conversion device 220, second electrode 230, and alkaline metal containing layer 240, which are described with reference to FIG. 2B may be provided. In addition, the metal grid 246 described with reference to FIGS. 2A and 6A may be also provided.

An antireflection layer 260 may be provided on the alkaline metal containing layer 240. The antireflection layer 260 may cover the alkaline metal containing layer 240. The alkaline metal containing layer 240 may be disposed between the antireflection layer 260 and the second electrode 230. The antireflection layer 260 may be formed of a same material as the antireflection layer 260 described with reference to FIG. 1A. The antireflection layer 260 may include an incident surface on which the light is incident from the light source LS. The antireflection layer 260 is configured to minimize the reflection of the light incident from the light source LS.

The metal grid 246 may contact the second electrode 240 through the alkaline metal containing layer 240 and the antireflection layer 260. Alternatively, as described with reference to FIG. 6B, the metal grid 246 may be provided between the second electrode 230 and the alkaline metal containing layer 240.

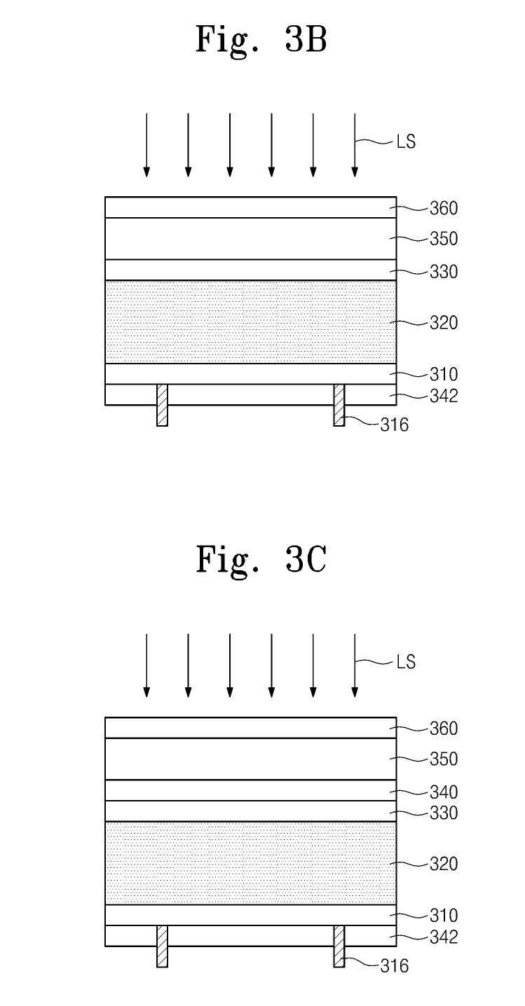

A solar cell according to third embodiment will be described hereinafter. FIG. 3A is a view of a solar cell according to third embodiment. The solar cell of this embodiment may be a transparent solar cell.

Referring to FIG. 3A, a solar cell includes a first electrode 310, a photovoltaic conversion device 320, and a second electrode 330. The first and second electrodes 310 and 330 may be formed of a transparent material. For example, the first and second electrodes 310 and 330 may be formed of at least one of ZnO:Al, ZnO:Ga, ZnO:B, ZnO:Cd, InSnO(ITO), SnO₂, SnO:F, RuO₂, IrO₂, and Gu₂O. The photovoltaic layer 320 may be one of the photovoltaic layers 120, 121, and 123 described with reference to FIGS. 1A, 5A, and 5B.

An alkaline metal containing layer 340 may be formed on glass substrate 350, and the glass substrate 350 may be coated with antireflection layer 360 on the opposite side. The alkaline metal containing layer 340 may be disposed between the glass substrate 350 and the second electrode 330. The glass substrate 350 may be disposed between the antireflection layer 360 and the alkaline metal containing layer 340. The alkaline metal containing layer 340, glass substrate 350, and antireflection layer 360 may be the alkaline metal containing layer 140, glass substrate 150, and antireflection layer 160, which are described with reference to FIG. 1A.

The first electrode 310 may include a first surface contacting the photovoltaic conversion device 320 and a second surface on the opposite side. A metal grid 316 may be disposed on the second surface of the first electrode 310. The metal grid 316 may protrude from the second surface of the first electrode 310. Like the metal grid 246 described with reference to FIG. 6A, the metal grid 316 may extend in a first direction parallel with the second surface of the photovoltaic conversion device 320, and further extend in a second direction parallel with the second surface of the photovoltaic conversion device 320 and intersect with the first direction. The second direction may interest the first direction at a right angle. Alternatively, the metal grid 316 may be composed of a plurality of conductive lines extending in the first direction.

The metal grid 316 may be formed of a same material as the metal grid 246 described with reference to FIG. 2A. The metal grid 316 may have a higher conductivity than the first electrode 310. By the metal grid 316 of higher conductivity, carriers generated in the photovoltaic conversion device 320 by the light source LS may be collected from the first electrode 310 and delivered to DC or AC load device with smaller loss of carriers.

The following will describe modified examples of the solar cell according to third embodiment of present invention.

FIG. 3B is a view of first modified example of the solar cell according to third embodiment of present invention.

Referring to FIG. 3B, the first electrode 310, photovoltaic conversion device 320, second electrode 330, which are described with reference to FIG. 3B, may be provided. The first electrode 310 may include electric charge compensation material. The electric charge compensation material may be a halogen element or a group-VI element. For example, the first electrode 310 may include one of fluorine (F), chlorine (Cl), bromine (Br), iodine (I), oxygen (O), sulphur (S), selenium (Se), and tellurium (Te). The electric charge compensation material enhances conductivity of the first electrode 310.

A glass substrate 350 may be disposed on the second electrode 330. The second electrode 330 may be disposed between the glass substrate 350 and the photovoltaic conversion device 320. An antireflection layer 360 may be disposed on the glass substrate 350. The glass substrate 350 may be disposed between the antireflection layer 360 and the second electrode 330. The glass substrate 350 and the antireflection layer 360 may respectively include same materials as the glass substrate 350 and the antireflection layer 360, which are described with reference to FIG. 3A.

The first electrode 310 may include a first surface contacting the photovoltaic conversion device 320 and a second surface on the opposite side. An alkaline metal containing layer 342 may be disposed on the second surface of the first electrode 310. The first electrode 310 may be disposed between the alkaline metal containing layer 342 and the photovoltaic conversion device 320. The alkaline metal containing layer 342 may be configured such that a reflectance for a first wavelength band of incident light may be higher than that for a second wavelength band of the incident light. The first wavelength band may be different from the second wavelength band. For example, the first wavelength band may include infrared rays or ultraviolet rays. The second wavelength band may include visible rays. The light having the first wavelength band reflected on the alkaline metal containing layer 342 is re-enetered the photovoltaic conversion device 320, thereby carriers (e.g., holes or electrons) may be generated in the photovoltaic conversion layer 320 due to the re-entered light.

The first and second wavelength bands may be adjusted depending on an optical thickness of the alkaline metal containing layer 342. The optical thickness is a value attained by multiplying a refractive index of a medium by a physical thickness of the medium. The refractive index of the alkaline metal containing layer 342 may be varied depending on a composition ratio of materials of the alkaline metal containing layer 342. The alkaline metal containing layer 342 may be formed of a same material as the alkaline metal containing layer 140 described with reference to FIG. 1A.

A metal grid passing through the alkaline metal containing layer 342 and contacting the first electrode 310 may be provided. Like the metal grid 246 in FIG. 6A, the metal gird 316 may extend in a first direction in parallel with the second surface of the photovoltaic conversion layer 320. The metal grid 316 may extend in a second direction that is in parallel with the second surface of the photovoltaic conversion device 320 and intersects the first direction. The second direction may intersect the first direction at a right angle. Alternatively, the metal grid 316 may be composed of a plurality of conductive lines extending in the first direction. The metal grid 316 may be formed of a same material as the metal grid 316 of FIG. 3A. The metal grid 316 may protrude from the alkaline metal containing layer 342 and the first electrode 310. Alternatively, as described with reference to FIG. 6B, the metal grid 316 may be disposed between the alkaline metal containing layer 342 and the first electrode 310.

FIG. 3C is a view of second modified example of the solar cell according to third embodiment of present invention.

Referring to FIG. 3C, the first electrode 310, photovoltaic conversion device 320, second electrode 330, alkaline metal containing layer 340, glass substrate 350, antireflection layer 360, and metal grid 316, which are described with reference to FIG. 3A, may be provided. The first electrode 310 may include a first surface contacting the photovoltaic conversion device 320 and a second surface on the opposite side. An additional alkaline metal containing layer 342 may be disposed on the second surface of the first electrode 310. The first electrode 310 may be disposed between the additional alkaline metal containing layer 342 and the photovoltaic conversion device 320. The additional alkaline metal containing layer 342 may be the alkaline metal containing layer 342 of FIG. 3B. The metal grid 316 may contact the first electrode 310 through the additional alkaline metal containing layer 342.

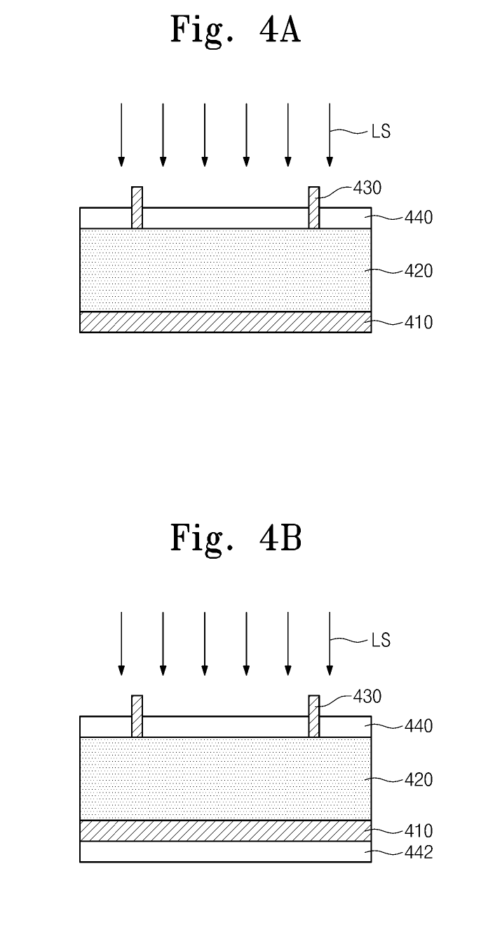

A solar cell according to fourth embodiment will now be described. FIG. 4A is a view of a solar cell according to fourth embodiment.

Referring to FIG. 4A, a solar cell includes a photovoltaic conversion device 420. The photovoltaic conversion device 420 is configured to generate carriers (e.g., holes or electrons) by the sunlight incident thereon. The photovoltaic conversion device 420 may include a first surface and a second surface on the opposite side. The photovoltaic conversion device 420 may include a first conductive type semiconductor layer and a second conductive type semiconductor layer, which may contact each other. The first and second conductive types may be different from each other. The first and second surfaces of the photovoltaic conversion device 420 may be surfaces having different types of semiconductor layers. For example, the first surface of the photovoltaic conversion device 420 may be a surface included in an N-type semiconductor layer and the second surface of the photovoltaic conversion layer 420 may be a surface included in a P-type semiconductor layer. The photovoltaic conversion layer 420 may include at least one of Si, SiGe, CuInS,

CuInGaSe, CuInGaS, CdS, CdTe, ZnO, ZnS, CuZnSnS, CuZnSnSe, Cu₂O, GaAs, GaInAs, GaInAlAs, and InP. The photovoltaic conversion device 420 may include an organic semiconductor material.

The first surface of the photovoltaic conversion device 420 may be connected to a first electrode 410. The first electrode 410 may be the first electrode 110 of FIG. 1A.

An alkaline metal containing layer 440 may be disposed on the first surface of the photovoltaic conversion device 420. The alkaline metal containing layer 440 may directly contact the first surface of the photovoltaic conversion device 420. The alkaline metal containing layer 440 may function as a antireflection layer for reducing the reflection of light incident from a light source LS. The alkaline metal containing layer 440 may be formed of a same material as the alkaline metal containing layer 140 of FIG. 1A. The alkaline metal contained in the alkaline metal containing layer 440 may be diffused to the photovoltaic conversion device 420 to improve the photovoltaic conversion efficiency of the photovoltaic conversion device 420. A portion of the photovoltaic conversion device 420, which contacts the alkaline metal containing layer 440 may be one of an amorphous, micro-crystal, and polycrystal layers that are formed through a film deposition process.

The second surface of the photovoltaic conversion device 420 may be connected to a second electrode 430. The second electrode 430 may be provided in the form of a metal grid contacting the photovoltaic conversion device 420. The second electrode 430 may directly contact the photovoltaic conversion device 420 through the alkaline metal containing layer 440. The second electrode 430 may protrude from the alkaline metal containing layer 440. Like the metal grid 246 of FIG. 6A, the second electrode 430 may extend in a first direction in parallel with the second surface of the photovoltaic conversion device 420. The second electrode 430 may extend in a second direction that is in parallel with the second surface of the photovoltaic conversion layer 420 and intersects the first direction. The second direction may intersect the first direction at a right angle. Alternatively, the second electrode 430 may be composed of a plurality of conductive lines extending in the first direction. The second electrode 430 may be formed of a same material as the metal grid 246 of FIG. 2A.

The following will describe a modified example of the solar cell according to fourth embodiment of present invention. FIG. 4B is a view of a modified example of the solar cell according to fourth embodiment of present invention.

Referring to FIG. 4B, the first electrode 410, photovoltaic conversion device 420, second electrode 430, and alkaline metal containing layer 440, which are described with reference to FIG. 4A, are provided. The first electrode 410 may include a first surface contacting the photovoltaic conversion device 420 and a second surface on the opposite side. An additional alkaline metal containing layer 442 may be disposed on the second surface of the first electrode 410. The first electrode 410 may be disposed between the additional alkaline metal containing layer 442 and the photovoltaic conversion device 420. The additional alkaline metal containing layer 442 may be formed of a same material as the alkaline metal containing layer 140 described with reference to FIG. 1A.

The alkaline metal in the alkaline metal containing layer 440 may be diffused to the photovoltaic conversion device 420. The alkaline metal in the additional alkaline metal containing layer 442 may be diffused to the photovoltaic conversion device 420 trough the first electrode 410.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A solar cell comprising:
a photovoltaic conversion device comprising a first surface and a second surface on the opposite side;
a first electrode connected to a first surface of the photovoltaic conversion device;
a second electrode connected to a second surface of the photovoltaic conversion device; and
an alkaline metal containing layer contacting one of the first and second electrodes.

2. The solar cell of claim 1, wherein the alkaline metal containing layer is provided on the second electrode to function as an antireflection layer, wherein the second electrode is disposed between the alkaline metal containing layer and the photovoltaic conversion device.

3. The solar cell of claim 2, further comprising:
a glass substrate disposed on the alkaline metal containing layer; and
an antireflection layer disposed on the glass substrate,
wherein the alkaline metal containing layer is disposed between the glass substrate and the second electrode;
the glass substrate is disposed between the antireflection layer and the alkaline metal containing layer; and
the alkaline metal containing layer has a larger refractive index than the glass substrate and a smaller refractive index than the second electrode.

4. The solar cell of claim 2, wherein the first electrode comprises a first surface contacting the photovoltaic conversion device and a second surface on the opposite side, wherein the solar cell further comprises a substrate covering the second surface of the first electrode and a metal grid contacting the second electrode through the alkaline metal containing layer.

5. The solar cell of claim 4, further comprising an antireflection layer on the alkaline metal containing layer, wherein the metal grid further passes through the antireflection layer.

6. The solar cell of claim 1, wherein the first electrode comprises a first surface contacting the photovoltaic conversion device and a second surface on the opposite side and the alkaline metal containing layer covers the second surface of the first electrode.

7. The solar cell of claim 6, further comprising:
a glass substrate on the second electrode; and
a antireflection layer on the glass substrate,
wherein the glass substrate is disposed between the second electrode and the antireflection layer.

8. The solar cell of claim 7, further comprising a metal grid contacting the first electrode through the alkaline metal containing layer.

9. The solar cell of claim 6, wherein the alkaline metal containing layer has a higher reflectance for a first wavelength band of incident light than a second wavelength band of the incident light, wherein the first wavelength band is different from the second wavelength band.

10. The solar cell of claim 9, wherein the second wavelength band comprises visible rays.

11. The solar cell of claim 6, further comprising an additional alkaline metal containing layer on the second electrode, wherein the second electrode is disposed between the additional alkaline metal containing layer and the photovoltaic conversion device.

12. The solar cell of claim 1, wherein the alkaline metal containing layer covers a top surface of the photovoltaic conversion device to function as a antireflection layer; and
the second electrode is a metal grid connected to the photovoltaic conversion device through the alkaline metal containing layer.

13. The solar cell of claim 12, wherein the first electrode comprises a first surface contacting the photovoltaic conversion device and a second surface on the opposite side, wherein the solar cell further comprises an additional alkaline metal containing layer covering the second surface of the first electrode.

14. The solar cell of claim 1, wherein the alkaline metal containing layer is disposed between the first surface of the photovoltaic conversion device and the first electrode and electrically connects the photovoltaic conversion device to the first electrode.

15. The solar cell of claim 1, wherein one of the first and second electrodes, which contacts the alkaline metal containing layer, comprises a halogen element or a group-IV element.

16. The solar cell of claim 1, wherein the alkaline metal containing layer comprises alkaline metal bonded to oxygen, boron, hydrogen, or fluorine.

17. The solar cell of claim 1, wherein the alkaline metal containing layer comprises alkaline metal as one of the chemical states of NaF, NaO, NaAlO₂, Na₂O-Al₂O₃-nSiO₂ (n is integer), NaBO₂, Na₂B₄O₇, NaBH₄, Na₂C₂, NaBH₄, Na₂O₂, Na₂Si₂O₅, Na₂SiO₃, and Na₄SiO₄

18. The solar cell of claim 1, wherein an amount of alkaline metal contained in the alkaline metal containing layer is about 5-20 percent by weight.

19. The solar cell of claim 1, wherein the photovoltaic conversion device comprises a plurality of PIN diodes.

20. The solar cell of claim 1, wherein the photovoltaic conversion device comprises a plurality of PN diodes.

21. The solar cell of claim 1, wherein the photovoltaic conversion device comprises at least one of Si, SiGe, CuInS, CuInSe, CuInGaSe, CuInGaS, CdS, CdTe, ZnO, ZnS, CuZnSnS, CuZnSnSe, Cu₂O, GaAs, GaInAs, GaInAlAs, and InP.

22. The solar cell of claim 1, wherein some of alkaline metal contained in the alkaline metal containing layer are diffused to the photovoltaic conversion device through one of the first and second electrodes, which contacts the alkaline metal containing layer.
